(19) United States
(12) Patent Application Publication
(10) Pub. No.: US 2013/0084208 A1
(43) Pub. Date: Apr. 4, 2013

(54) ALUMINUM-BASED ALLOYS

(71) Applicant: Quest Tek Innovations LLC, Evanston, IL (US)

(72) Inventors: Abhijeet Misra, Chicago, IL (US); James A. Wright, Wilmette, IL (US)

(73) Assignee: QUESTEK INNOVATIONS LLC, Evanston, IL (US)

(21) Appl. No.: 13/626,602

(22) Filed: Sep. 25, 2012

Related U.S. Application Data
(60) Provisional application No. 61/541,564, filed on Sep. 30, 2011.

(51) Int. Cl. C22C 21/10; C22F 1/053; C23C 16/06; B22D 25/00

(52) U.S. Cl. 420/540; 164/47; 164/122; 148/500; 427/250

(57) ABSTRACT

In an aspect the disclosure relates to an alloy comprising, by weight, about 0.15% to about 1.00% zinc, 0% to about 0.20% gallium, and the balance aluminum and incidental elements and impurities, wherein the alloy has a corrosion potential from about −0.85 V to about −0.73 V relative to a saturated calomel electrode.

### FEDERALLY-SPONSORED RESEARCH AND DEVELOPMENT

This invention was made with government support under Contract Nos. N65538-09-M-0088 and N00024-10-C-4172 awarded by the U.S. Government, Naval Sea Systems Command. The government has certain rights in the invention.

### BACKGROUND

Stainless steels such as the 15-5 PH stainless steel are employed in marine environments, but they are susceptible to corrosion. To mitigate corrosion, the steel may be coupled to alloys having a lower corrosion potential. Steel typically has a corrosion potential from about −0.73 V to about −0.85V (relative to a saturated calomel electrode, as will be all corrosion potentials hereinafter). Generally, alloys with a lower corrosion potential are less noble, i.e., less resistant to corrosion. When coupled to steel, such alloys can sacrificially oxidize as an anode. This is known as providing a cathodic protection to the steel. The difference in corrosion potentials between the steel cathode and the sacrificial anode drives an electrical current that helps confine the oxidation reaction to the anode. At the steel cathode, a reduction reaction occurs, which may cause the cathode to be charged with hydrogen. Hydrogen charging can lead to undesirable hydrogen embrittlement and stress-corrosion cracking The deleterious effects of hydrogen charging are more pronounced in high-strength steels. Generally speaking, larger differences in corrosion potentials can lead to a greater driving force for the undesirable hydrogen charging at the cathode. That is, a corrosion potential that is highly negative can be undesirable for a sacrificial anode. Thus, there has developed a need for an anode material with a corrosion potential that is sufficiently lower than steel to provide cathodic protection yet high enough to reduce hydrogen charging at the cathode.

Various alloys based on zinc or aluminum have been explored as anode materials. Pure zinc shows a corrosion potential of about −1.05 V. Typically the corrosion potential for zinc-based alloys induces hydrogen charging and hydrogen embrittlement. Moreover, zinc may be associated with a generally low current-carrying capacity. Similar to the zinc-based anodes, commercial aluminum-based anodes show a corrosion potential of about −1.10 V, which again is too negative, and likewise leads to hydrogen charging. Pure aluminum shows a higher corrosion potential of about −0.85 V, which is better for reducing hydrogen charging. However, aluminum forms an aluminum oxide that can be inefficient for cathodic protection, limiting the electrochemical anode efficiency to about 70%. Thus, there has developed a need for an anode material having a corrosion potential within a desired range and having a suitably high electrochemical anode efficiency.

### SUMMARY

In an aspect the disclosure relates to an alloy comprising, by weight, about 0.15% to about 1.00% zinc, 0% to about 0.20% gallium, and the balance aluminum and incidental elements and impurities, wherein the alloy has a corrosion potential from about −0.85 V to about −0.73 V relative to a saturated calomel electrode.

In another aspect the disclosure relates to a method of producing an alloy, the method comprising casting an amount of zinc, aluminum, and optionally gallium under conditions that allow for formation of the alloy, wherein the alloy has a corrosion potential (V_{eff}) relative to a saturated calomel electrode from about −0.85 V to about −0.73 V, and the corrosion potential is determined according to the following equation

V_{eff}=7.32×(100−w_{Ga}−w_{Zn})+104.9×w_{Zn}+507.5×w_{Ga}−188.2×w_{Ga}×w_{Zn}

wherein w_{Zn} and w_{Ga} are weight percentages of zinc and gallium, respectively, in the alloy.

In yet another aspect the disclosure relates to a method of coating an alloy on a substrate, the method comprising contacting a surface of the substrate with an amount of the alloy, wherein the alloy comprises zinc, aluminum, and optionally gallium and wherein the alloy has a corrosion potential (V_{eff}) from about −0.85 V to about −0.73 V, and the corrosion potential is determined according to the following equation

V_{eff}=7.32×(100−w_{Ga}−w_{Zn})+104.9×w_{Zn}+507.5×w_{Ga}−188.2×w_{Ga}×w_{Zn}

wherein w_{Zn} and w_{Ga} are weight percentages of zinc and gallium, respectively, in the alloy.

Other aspects and embodiments will become apparent in light of the following description and accompanying drawings.

### BRIEF DESCRIPTION OF THE DRAWINGS

FIG. 1 is a graph plotting the corrosion potential of non-limiting embodiments of alloys falling within the scope of the disclosure.

### DETAILED DESCRIPTION

Aspects relate to alloys, manufactured articles comprising the alloys, and methods for producing the alloys as described herein. Other aspects and embodiments will be apparent in light of the following detailed description.

A “corrosion potential” as used herein includes definitions that are generally known in the chemical/electrochemical art, and can be measured relative to a saturated calomel electrode or relative to saturated silver/silver chloride in seawater. Unless noted otherwise, all corrosion potentials listed herein are measured relative to a saturated calomel electrode.

An “anode” as used herein refers to an electrode where oxidation occurs.

A “cathode” as used herein refers to an electrode where reduction occurs.

An “anode efficiency” or “electrochemical efficiency” as used herein refers to the current-carrying capacity of the anode divided by a theoretically obtainable total capacity.

Any recited range described herein is to be understood to encompass and include all values within that range, without the necessity for an explicit recitation. Use of the word “about” to describe a particular recited amount or range of amounts is meant to indicate that values near to the recited amount are included in that amount, such as, but not limited to, values that could or naturally would be accounted for due to instrument and/or human error in forming measurements.

Aluminum-based alloys having a corrosion potential between those of pure aluminum and steel are provided. The alloys include zinc and gallium in amounts suitable to provide cathodic protection. Cathodic protection is a technique to reduce corrosion of a metal surface by making that surface the cathode of an electrochemical cell. In some embodiments, the disclosed aluminum-based alloys may be suitable to provide cathodic protection for a metal surface may be made out of steel or nickel-based high strength alloys such as Monel K-500 having a nominal composition of about 29.5% copper, about 2.7% aluminum, about 0.6% titanium, about 0.18% carbon, about 2.0% iron, about 1.5% manganese, about 0.50% silicon, about 0.010% sulfur, by weight, and the balance nickel and incidental elements and impurities. In other embodiments, the disclosed aluminum-based alloys are suitable to provide cathodic protection for other metal surfaces that are immersed in a corrosion-prone situation, such as naval ships and submarines that are immersed in seawater or saltwater. The disclosed alloys can be used in manufactured articles including, but not limited to, a sacrificial anode. The alloys would also be useful for numerous other applications wherein a corrosion potential lower than steel, a suitably high electrochemical anode efficiency, or both are desired.

According to one aspect, the disclosed alloys can suitably reduce hydrogen charging at the cathode. Cathodic protection frequently produces hydrogen on the cathode, i.e., the protected steel or nickel-based high strength alloys. The produced hydrogen may diffuse to stress concentrations and potentially cause cracking of the steel or nickel-based high strength alloys. For example, when immersed in seawater or saltwater, Monel K-500 can show significant hydrogen uptake, potentially leading to hydrogen-assisted in-service cracking after a long-term exposure ranging from about 1 year to about 10 years. The disclosed alloys, however, are associated with a corrosion potential that is carefully selected to reduce hydrogen charging at the cathode.

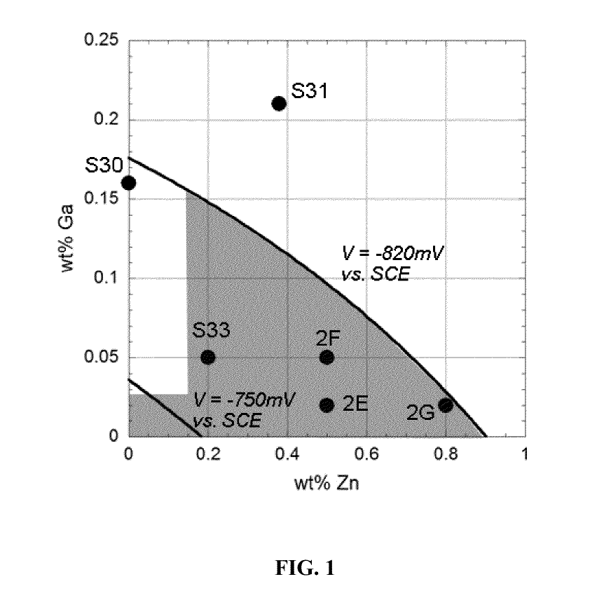

FIG. 1 relates to alloys that generally include suitable concentrations of zinc and gallium to provide a corrosion potential relative to a saturated calomel electrode from about −0.85 V to about −0.73 V. In some embodiments, the corrosion potential may be about −0.85 V or more, about −0.84 V or more, about −0.83 V or more, about −0.82 V or more, about −0.81 V or more, about −0.80 V or more, about −0.79 V or more, about −0.78 V or more, about −0.77 V or more, about −0.76 V or more, about −0.75 V or more, or about −0.74 V or more. The corrosion potential may also be about −0.73 V or less, about −0.74 V or less, about −0.75 V or less, about −0.76 V or less, about −0.77 V or less, about −0.78 V or less, about −0.79 V or less, about −0.80 V or less, about −0.81 V or less, about −0.82 V or less, about −0.83 V or less, or about −0.84 V or less. This includes corrosion potential ranges from about −0.84 V to about −0.76 V, about −0.83 V to about −0.77 V, about −0.82 V to about −0.78 V, and −0.82 V to about −0.75 V. Depending on the usage requirements or preferences for the particular alloy, a corrosion potential more negative than about −0.85 V may undesirably lead to hydrogen embrittlement, while a corrosion potential more positive than about −0.73 V may undesirably lead to general corrosion or rusting. FIG. 1 illustrates a shaded composition window of zinc and gallium for alloys having a corrosion potential from about −0.82 V to about −0.75 V. It is understood that any composition within the shaded composition window may be an embodiment of the alloys described herein.

In the course of this work, a Redlich-Kister polynomial was developed to approximate the corrosion potential relative to a saturated calomel electrode of aluminum-based alloys that include zinc and gallium. The polynomial is based on a regression analysis of literature data and example alloys. The polynomial is as follows:

V_{eff}=k_{Al}×(100×w_{Ga}−w_{Zn})+k_{Zn}×w_{Zn}+k_{Ga}×w_{Ga}+k_{GaZn}×w_{Ga}×w_{Zn} [1]

where w_{Zn} and w_{Ga} are the weight percentages of zinc and gallium, respectively, in the alloy; and k_{Al}, k_{Zn}, k_{Ga}, and k_{GaZn} are constants that are calculated to minimize the root-mean-square error between the calculated and measured corrosion potentials of aluminum-based alloys. The calculated values of k_{Al}, k_{Zn}, k_{Ga}, and k_{GaZn} are 7.32, 104.9, 507.5 and −188.2, respectively. Suitable concentrations of zinc and gallium can be computed with the above polynomial using the calculated values of k_{Al}, k_{Zn}, k_{Ga}, and k_{GaZn}.

In an embodiment, the alloy comprises, by weight, about 0.15% to about 1.00% zinc, 0% to about 0.20% gallium, and the balance aluminum and incidental elements and impurities, wherein the alloy has a corrosion potential from about −0.85 V to about −0.73 V relative to a saturated calomel electrode. In some embodiments, incidental elements and impurities in the disclosed alloys may include iron, silicon, manganese, or titanium, or a mixture thereof. The incidental elements and impurities may be present in the alloys disclosed herein in amounts no more than 0.1% by weight for each. It is to be appreciated that the alloys described herein may consist only of the above-mentioned constituents or may consist essentially of such constituents, or in other embodiments, may include additional constituents.

According to one aspect, the disclosed alloys are associated with a suitably high electrochemical anode efficiency, e.g., about 80% or higher when tested according to NACE (National Association of Corrosion Engineers) specification TM-0190. For at least the past fifteen years, certain aluminum-based alloys have been used as a consumable anode for cathodic protection. For example, an anode may be out of an aluminum-based alloy having a nominal composition of 0.10% gallium by weight, and the balance aluminum and incidental elements and impurities. When cast as an anode, however, this aluminum-based alloy shows a relatively low electrochemical efficiency. For example, an anode measuring 38 mm in diameter and 16.8 mm in height showed an electrochemical efficiency of 80% according to a NACE test with a 15-day exposure, and 70% according to a DNV (Der Norske Veritas) test with a 4-day exposure. The U.S. Navy reported that the efficiency of this alloy is only 67.70% after a 4-day exposure at the Naval Research Laboratory test facility in Key West, Fla. (E. Lemieux, Keith E. Lucas, E. A. Hogan & A. M. Grolleau, Performance Evaluation of Low Voltage Anodes for Cathodic Protection, in CORROSION 2002, Paper No. 02016 (2002) (incorporated by reference herein)). Moreover, the efficiency is further reduced in long-term exposure for over a year, down to 56%. Thus, there has developed a need for an anode material having a long-term corrosion potential within a desired range and having a suitably high electrochemical anode efficiency. Others in the industry, however, have failed to meet this need for at least the past fifteen years.

The prior art teaches away from adding zinc and gallium to an aluminum alloy for cathodic protection. For example, ternary Al—Zn—Ga anodes made out of an aluminum-based alloys having a nominal composition of, by weight, 0.2% gallium, 0.5% gallium, or 1% gallium, in combination with 2% zinc or 4% zinc were reported to result in a corrosion potential more negative than −0.95 V (E. Aragon, L. Cazenave-Vergez, E. Lanza, A. Giroud & A. Sebaoun, Influence of alloying elements on electrochemical behaviour of ternary Al—Zn—Ga alloys for sacrificial anodes, 32(4) BRITISH CORROSION JOURNAL 263-68 (1997) (incorporated by reference herein)). As detailed above, a highly negative corrosion potential can undesirably lead to hydrogen charging. Thus, the prior art again teaches away from adding zinc and gallium to an aluminum alloy to achieve an anode material having a corrosion potential within a desired range. Moreover, ternary Al—Zn—Ga anodes were also reported as not being helpful in improving the anode efficiency compared to binary Al—Ga anodes. In fact, the addition of zinc to binary Al—Ga anodes were reported to reduce the efficiency, from 43% (Al-1% Ga, by weight) to 23% (Al-4% Zn-1% Ga, by weight) or from 66% (Al-2% Zn-0.5% Ga, by weight) to 63% (Al-4% Zn-0.5% Ga, by weight). Thus, the prior art again teaches away from adding zinc and gallium to an aluminum alloy to achieve an anode material having a suitably high electrochemical anode efficiency. As such, in surveying all possible ternary aluminum alloys as an anode material, the prior art recognized alloys such as Al—In—Zn, but failed to recognize Al—Zn—Ga as a suitable anode material (J. T. Reding & J. J. Newport, The Influence of Alloying Elements on Aluminum Anodes in Sea Water, 5(12) MATER PROTECT. 15-18 (1966) (incorporated by reference herein)). Thus, one of ordinary skill in the art could not have arrived at the alloys disclosed herein for use as an anode.

According to another aspect, a method of producing an alloy is provided, the method generally including casting an alloy that has a corrosion potential (V_{eff}) computed according to equation [1] and cooling the cast alloy at a rate below about 0.06° C. per second so as to completely or substantially eliminate as-cast segregation of gallium and if desirable, other components. According to yet another aspect, a method of producing an alloy is provided, the method generally including casting an alloy that has a corrosion potential (V_{eff}) computed according to equation [1] and subjecting the alloy to a heat treatment at about 600° C. for about 1 hour so as to substantially or completely eliminate the as-cast segregation of gallium and if desirable, other components. Where an anode with substantially uniform corrosion characteristics is desired, the disclosed alloys can be useful.

To select compositions with a suitable microstructure and methods for processing the compositions, solidification calculations can be used. For example, thermodynamics calculation packages such as Thermo-Calc® software version N offered by Thermo-Calc Software AB of Sweden can be used with aluminum-based thermodynamic and mobility databases that QuesTek Innovations LLC developed based on open-literature data.

In some embodiments, segregation can be completely or substantially eliminated by cooling the disclosed alloys at a slow rate, such as about 0.06° C. per second or less, about 0.05° C. per second or less, about 0.04° C. per second or less, about 0.03° C. per second or less, about 0.02° C. per second or less, or about 0.01° C. per second or less, during solidification. In other embodiments, the disclosed alloys can be cooled at a rate such as about 1° C. per second until the alloy reaches the solidus temperature, and subsequently at a faster rate, such as about 5° C. per second. The fast-cooled alloy can then be subjected to a homogenization heat treatment at about 600° C. for about 1 hour, to substantially or completely eliminate the as-cast segregation.

Some samples exemplary of embodiments of the alloys disclosed herein were prepared and tested for physical properties. The examples are described in greater detail below as illustrative non-limiting embodiments. Additionally, counterexamples (samples S30 and S31) were also prepared and tested for comparison. Some examples and counterexamples described herein are identified by black circles on FIG. 1.

### EXAMPLE 1

### Sample S30

A melt was prepared with the nominal composition, in weight percentage, of about 0.16% Ga, and the balance aluminum and incidental elements and impurities. The melt weighed about 100 g and was shaped as a rectangular box measuring about 3 cm by about 4 cm by about 5 cm. Sample S30 is a counterexample. A sample of this embodiment was cooled in a furnace at about 0.06° C. per hour and tested according to NACE specification TM-0190 under an impressed current of about 6.2 A/m² at room temperature, i.e., about 20° C. to about 25° C. The calculated potential was −0.81 V; however, during 14 days of exposure to synthetic seawater, the corrosion potential averaged about −0.87 V, which is below the desired potential of about −0.85 V to about −0.73 V. The anode current capacity measured about 2,526 Amp-hr/kg and the anode efficiency measured about 85%.

### EXAMPLE 2

### Sample S31

A melt was prepared with the nominal composition, in weight percentage, of about 0.21% Ga, about 0.38% Zn, and the balance aluminum and incidental elements and impurities. The melt weighed about 100 g and was shaped as a rectangular box measuring about 3 cm by about 4 cm by about 5 cm. Sample S31 is a counterexample. The calculated potential was −0.86 V. A sample of this embodiment was cooled in a furnace at about 0.06° C. per hour and tested according to NACE specification TM-0190 under an impressed current of about 6.2 A/m² at room temperature. During 14 days of exposure to synthetic seawater, the corrosion potential averaged about −0.89 V, which is below the desired potential of about −0.85 V to about −0.73 V. The anode current capacity measured about 2,397 Amp-hr/kg and the anode efficiency measured about 80%.

### EXAMPLE 3

### Sample S33

A melt was prepared with the nominal composition, in weight percentage, of about 0.05% Ga, about 0.20% Zn, and the balance aluminum and incidental elements and impurities. The melt weighed about 100 g and was shaped as a rectangular box measuring about 3 cm by about 4 cm by about 5 cm. The calculated potential was −0.78 V. A sample of this embodiment was cooled in a furnace at about 0.06° C. per hour and tested according to NACE specification TM-0190 under an impressed current of about 6.2 A/m² at room temperature. During 14 days of exposure to synthetic seawater, the corrosion potential averaged about −0.80 V, which is within the desired potential of about −0.85 V to about −0.73 V. The anode current capacity measured about 2,526 Amp-hr/kg and the anode efficiency measured about 85%.

### EXAMPLE 4

### Sample 2E

A melt was prepared with the nominal composition, in weight percentage, of about 0.02% Ga, about 0.50% Zn, and the balance aluminum and incidental elements and impurities. The incidental elements and impurities included about 0.04% in weight percentage of silicon and iron. The melt weighed about 100 g and was shaped as a rectangular box measuring about 3 cm by about 4 cm by about 5 cm. The calculated potential was −0.79 V. A sample of this embodiment was cooled about 1° C. per second until the solidus temperature, and subsequently at about 5° C. per second. The cooled sample was then subjected to a homogenization heat treatment at about 600° C. for about 1 hour. The homogenized sample was tested according to NACE specification TM-0190 under an impressed current of about 6.2 A/m² at room temperature. During 14 days of exposure to synthetic seawater, the corrosion potential averaged about −0.78 V, which is within the desired potential of about −0.85 V to about −0.73 V. The anode current capacity measured about 2,598 Amp-hr/kg and the anode efficiency measured about 87%.

### EXAMPLE 5

### Sample 2F

A melt was prepared with the nominal composition, in weight percentage, of about 0.05% Ga, about 0.50% Zn, and the balance aluminum and incidental elements and impurities. The incidental elements and impurities included about 0.04% in weight percentage of silicon and iron. The melt weighed about 100 g and was shaped as a rectangular box measuring about 3 cm by about 4 cm by about 5 cm. The calculated potential was −0.80 V. A sample of this embodiment was cooled about 1° C. per second until the solidus temperature, and subsequently at about 5° C. per second. The cooled sample was then subjected to a homogenization heat treatment at about 600° C. for about 1 hour. The homogenized sample was tested according to NACE specification TM-0190 under an impressed current of about 6.2 A/m² at room temperature. During 14 days of exposure to synthetic seawater, the corrosion potential averaged about −0.81 V, which is within the desired potential of about −0.85 V to about −0.73 V. The anode current capacity measured about 2,598 Amp-hr/kg and the anode efficiency measured about 87%.

### EXAMPLE 6

### Sample 2G

A melt was prepared with the nominal composition, in weight percentage, of about 0.02% Ga, about 0.80% Zn, and the balance aluminum and incidental elements and impurities. The incidental elements and impurities included about 0.04% in weight percentage of silicon and iron. The melt weighed about 100 g and was shaped as a rectangular box measuring about 3 cm by about 4 cm by about 5 cm. The calculated potential was −0.82 V. A sample of this embodiment was cooled about 1° C. per second until the solidus temperature, and subsequently at about 5° C. per second. The cooled sample was then subjected to a homogenization heat treatment at about 600° C. for about 1 hour. The homogenized sample was tested according to NACE specification TM-0190 under an impressed current of about 6.2 A/m² at room temperature. During 14 days of exposure to synthetic seawater, the corrosion potential averaged about −0.80 V, which is within the desired potential of about −0.85 V to about −0.73 V. The anode current capacity measured about 2,569 Amp-hr/kg and the anode efficiency measured about 86%.

The following Table 1 summarizes the corrosion characteristics of the examples and counterexamples set forth above.

TABLE 1

| | Average corrosion | | |
|---|---|---|---|
| | potential during 14 | Anode current | |
| Sample ID | days of exposure | capacity | Anode efficiency |
| S30 | −0.87 V | 2,526 Amp-hr/kg | 85% |
| S31 | −0.89 V | 2,397 Amp-hr/kg | 80% |
| S33 | −0.80 V | 2,526 Amp-hr/kg | 85% |
| 2E | −0.78 V | 2,582 Amp-hr/kg | 87% |
| 2F | −0.81 V | 2,591 Amp-hr/kg | 87% |
| 2G | −0.80 V | 2,584 Amp-hr/kg | 86% |

### EXAMPLE 7

### Sample LSS-10

A plurality of samples were cast with the nominal composition, in weight percentage, of about 0.02% Ga, about 0.50% Zn, and the balance aluminum and incidental elements and impurities. The incidental elements and impurities included about 0.04% Fe and about 0.04% Si, in weight percentage. Each sample weighed about 3.9 kg to about 4.1 kg. Some samples were subjected to a homogenization heat treatment, while others were kept as-cast. Both types of samples were tested according to NACE specification TM-0190. The anode current capacity measured about 2,460 Amp-hr/kg for the as-cast samples, and about 2,410 Amp-hr/kg for the homogenized samples. The anode efficiency measured about 82.5% for the as-cast samples, and about 80.8% for the homogenized samples, both of which are higher than the reported efficiency of Al-0.10% Ga (80% under the NACE test).

Both types of samples were also tested according to DNV-RP-B401. The sample container included a minimum of 10 liters of artificial seawater that was prepared according to ASTM D 1141-52. The artificial seawater in the sample container was used as an electrolyte in an electrolytic cell. Cylindrical samples with a diameter of 10±1 mm and a length of 50±5 mm were exposed in the sample containers and continuously purged with air during the entire test. Steel screen cathodes were employed for each test. Each steel screen cathode measured a minimum of 20 times of the exposed surface area of the respective sample. The following current densities were used: about 1.5 mA/cm² on day 1, about 0.4 mA/cm² on day 2, about 4.0 mA/cm² on day 3, and about 1.5 mA/cm² on day 4. The anode current capacity measured about 2,470 Amp-hr/kg for the as-cast samples, and about 2,560 Amp-hr/kg for the homogenized samples. The anode efficiency measured about 83% for the as-cast samples, and about 86% for the homogenized samples, both of which are higher than the reported efficiency of Al-0.10% Ga (70% under the DNV test).

The following Table 2 summarizes the corrosion characteristics of the samples set forth above.

TABLE 2

| | Average corrosion | Anode current | Anode |
|---|---|---|---|
| Sample ID | potential | capacity | efficiency |
| As-cast 1 | −0.76 V | 2,471 Amp-hr/kg | 83% |
| As-cast 2 | −0.76 V | 2,473 Amp-hr/kg | 83% |
| As-cast 3 | −0.75 V | 2,447 Amp-hr/kg | 82% |
| As-cast 4 | −0.75 V | 2,447 Amp-hr/kg | 82% |
| Homogenized 1 | −0.76 V | 2,401 Amp-hr/kg | 80% |
| Homogenized 2 | −0.75 V | 2,412 Amp-hr/kg | 81% |
| Homogenized 3 | −0.75 V | 2,412 Amp-hr/kg | 81% |
| Homogenized 4 | −0.75 V | 2,407 Amp-hr/kg | 81% |

It is understood that the disclosure may embody other specific forms without departing from the spirit or central characteristics thereof The disclosure of aspects and embodiments, therefore, are to be considered as illustrative and not restrictive. While specific embodiments have been illustrated and described, other modifications may be made without significantly departing from the spirit of the invention. Unless noted otherwise, all percentages listed herein are weight percentages.

What is claimed is:

1. An alloy, comprising, by weight, about 0.15% to about 1.00% zinc, 0% to about 0.20% gallium, and the balance aluminum and incidental elements and impurities, wherein the alloy has a corrosion potential from about −0.85 V to about −0.73 V relative to a saturated calomel electrode.

2. The alloy of claim 1, wherein the zinc content is about 0.40% to about 1.00% and the gallium content is 0% to about 0.10%.

3. The alloy of claim 2, wherein the zinc content is about 0.50% to about 0.80% and the gallium content is about 0.02% to about 0.05%.

4. The alloy of claim 1, wherein the corrosion potential is about −0.84 V to about −0.76 V relative to a saturated calomel electrode.

5. The alloy of claim 4, wherein the corrosion potential is about −0.82 V to about −0.75 V relative to a saturated calomel electrode.

6. The alloy of claim 1, wherein the corrosion potential (V_{eff}) is computed according to the following equation
V_{eff}=7.32×(100−w_{Ga}−w_{Zn})+104.9×w_{Zn}+507.5×w_{Ga}−188.2×w_{Ga}×w_{Zn}
where w_{Zn} and w_{Ga} are weight percentages of zinc and gallium, respectively, in the alloy.

7. The alloy of claim 6, wherein the corrosion potential is about −0.84 V to about −0.76 V relative to a saturated calomel electrode.

8. The alloy of claim 6, wherein the corrosion potential is about −0.82 V to about −0.75 V relative to a saturated calomel electrode.

9. An anode comprising the alloy of claim 1.

10. The alloy of claim 1, wherein the alloy is associated with an electrochemical anode efficiency of about 80% or higher using a NACE TM-0190 specimen weighing about 0.5 kg or more.

11. A method of producing an alloy, the method comprising:
casting an alloy that has a corrosion potential (V_{eff}) relative to a saturated calomel electrode from about −0.85 V to about −0.73 V, the corrosion potential computed according to the following equation
V_{eff}=7.32×(100−w_{Ga}−w_{Zn})+104.9×w_{Zn}+507.5×w_{Ga}−188.2×w_{Ga}×w_{Zn}
where w_{Zn} and w_{Ga} are weight percentages of zinc and gallium, respectively, in the alloy.

12. The method of claim 11, further comprising:
cooling the cast alloy at a rate below about 0.06° C. per second so as to substantially or completely eliminate as-cast segregation of gallium.

13. The method of claim 11, further comprising:
subjecting the alloy to a heat treatment at about 600° C. for about 1 hour so as to substantially or completely eliminate the as-cast segregation of gallium.

14. The method of claim 11, wherein the coating of the alloy includes by weight, about 0.15% to about 1.00% zinc, 0% to about 0.20% gallium, and the balance aluminum and incidental elements and impurities.

15. The method of claim 14, wherein the zinc content is about 0.40% to about 1.00% and the gallium content is 0% to about 0.10%.

16. The method of claim 15, wherein the zinc content is about 0.50% to about 0.80% and the gallium content is about 0.02% to about 0.05%.

17. A method of coating an alloy on a substrate, the method comprising:
contacting a surface of the substrate with an amount of the alloy, wherein the alloy comprises zinc, aluminum, and optionally gallium and wherein the alloy has a corrosion potential (V_{eff}) from about −0.85 V to about −0.73 V, and the corrosion potential is determined according to the following equation
V_{eff}=7.32×(100−w_{Ga}−w_{Zn})+104.9×w_{Zn}+507.5×w_{Ga}−188.2×w_{Ga}×w_{Zn}
where w_{Zn} and w_{Ga} are weight percentages of zinc and gallium, respectively, in the alloy.

18. The method of claim 17, wherein the coating is applied by ion vapor deposition.

19. The method of claim 17, wherein the coating of the alloy includes by weight, about 0.15% to about 1.00% zinc, 0% to about 0.20% gallium, and the balance aluminum and incidental elements and impurities.

20. The method of claim 17, wherein the zinc content is about 0.40% to about 1.00% and the gallium content is 0% to about 0.10%.
